(19) United States
(12) Patent Application Publication
(10) Pub. No.: US 2021/0036392 A1
(43) Pub. Date: Feb. 4, 2021

(54) SURFACE MOUNT MICROWAVE DEVICE AND ASSEMBLY

(71) Applicant: Molex, LLC, Lisle, IL (US)

(72) Inventors: Andrey TAYKOV, Quebec (CA); Nikolay VOLOBUEV, Quebec (CA)

(73) Assignee: Molex, LLC, Lisle, IL (US)

(21) Appl. No.: 16/644,957

(22) PCT Filed: Sep. 5, 2018
(86) PCT No.: PCT/US2018/049458

§ 371 Date: Mar. 5, 2020

Related U.S. Application Data
(60) Provisional application No. 62/554,741, filed on Sep. 6, 2017.

(51) Int. Cl. H01P 1/36; H05K 1/18; H05K 1/02

(52) U.S. Cl. CPC H01P 1/36; H05K 1/0243; H05K 1/181

(57) ABSTRACT

A microwave device (10) configured for surface mounting on a circuit board includes first and second conductive members adjacent a mounting surface of the device. The first and second conductive members are devoid of solder pads. An assembly includes a microwave device and a circuit board on which the microwave device is mounted. The circuit board includes signal conductors that are devoid of solder pads.

### RELATED APPLICATIONS

This application claims priority to U.S. Provisional Application No. 62/554,741, filed Sep. 6, 2017, which is incorporated herein by reference in its entirety.

### TECHNICAL FIELD

The present disclosure relates generally to microwave devices and, more particularly, to circulators and isolators capable of being surface mounted to a circuit board or member.

### BACKGROUND

When operating an electronic system at relatively high speeds, small discontinuities and changes in impedance may significantly impact the operation of the system. The interconnection between components and a circuit board or member often causes such discontinuities and change in impedance. In particular, surface mount junctions between a component and a circuit board may cause in increase in capacitance and a resultant undesirable change in impedance along the transmission lines of the system.

Attempts to reduce the size of surface mount junctions often increases the complexity of mounting and soldering surface mount components to a circuit board. Such increased complexity may increase the cost and/or quality of the resultant mounting process.

### SUMMARY

In one aspect, a microwave device includes a first dielectric member with a first outward surface and an oppositely facing first inward surface and a first conductive layer disposed on the first outward surface of the first dielectric member and a second dielectric member with a second outward surface defining a mounting direction of the microwave device and an oppositely facing second inward surface and a second conductive layer disposed on the second outward surface of the second dielectric member. One of the first dielectric member and the second dielectric member have a central bore aligned with a central axis of the microwave device and a ferrite element is disposed within the central bore and a magnetic element is aligned with the central bore. A conductive element is disposed between the first inward surface of the first dielectric member and the second inward surface of the second dielectric member, with the conductive element having a central section along with the central axis and first, second and third transmission lines electrically connected to the central section and extending therefrom. A first conductive member is electrically connected to the first transmission line with the first conductive member extending from the first transmission line to the second outward surface of the second dielectric member and being spaced from the second conductive layer. A second conductive member is electrically connected to the second transmission line with the second conductive member extending from the second transmission line to the second outward surface of the second dielectric member and being spaced from the second conductive layer. A third conductive member is electrically connected to the third transmission line and the first conductive member and the second conductive member are not electrically connected to solder pads on the microwave device.

In another aspect, an assembly includes a circuit member and a microwave device. The circuit member includes a mounting surface, a ground plane, and first and second signal conductors spaced from the ground plane. The microwave device includes a first dielectric member with a first outward surface and an oppositely facing first inward surface and a first conductive layer disposed on the first outward surface of the first dielectric member and a second dielectric member with a second outward surface defining a mounting direction of the microwave device and an oppositely facing second inward surface and a second conductive layer disposed on the second outward surface of the second dielectric member. One of the first dielectric member and the second dielectric member have a central bore aligned with a central axis of the microwave device and a ferrite element is disposed within the central bore and a magnetic element is aligned with the central bore. A conductive element is disposed between the first inward surface of the first dielectric member and the second inward surface of the second dielectric member, with the conductive element having a central section along with the central axis and first, second and third transmission lines electrically connected to the central section and extending therefrom. A first conductive member is electrically connected to the first transmission line with the first conductive member extending from the first transmission line to the second outward surface of the second dielectric member and being spaced from the second conductive layer and the first conductive member being mechanically and electrically connected to the first signal conductor of the circuit member by solder at a first interconnection. A second conductive member is electrically connected to the second transmission line with the second conductive member extending from the second transmission line to the second outward surface of the second dielectric member and being spaced from the second conductive layer and the second conductive member being mechanically and electrically connected to the second signal conductor of the circuit member by solder at a second interconnection. A third conductive member is electrically connected to the third transmission line and the first and second signal conductors are devoid of solder pads adjacent the first and second interconnections.

In still another aspect, an assembly includes a circuit member and a microwave device. The circuit member includes a mounting surface, a ground plane, a first signal conductors spaced from the ground plane with the first signal conductor being devoid of a solder pad and having a first width adjacent a first interconnection location, and a second signal conductor spaced from the ground plane with the second signal conductor being devoid of a solder pad and having a second width adjacent a second interconnection location. The microwave device includes a first dielectric member with a first outward surface and an oppositely facing first inward surface and a first conductive layer disposed on the first outward surface of the first dielectric member and a second dielectric member with a second outward surface defining a mounting direction of the microwave device and an oppositely facing second inward surface and a second conductive layer disposed on the second outward surface of the second dielectric member. One of the first dielectric member and the second dielectric member have a central bore aligned with a central axis of the microwave device and a ferrite element is disposed within the central bore and a magnetic element is aligned with the central bore. A conductive element is disposed between the first inward surface of the first dielectric member and the second inward surface of the second dielectric member, with the conductive element having a central section along with the central axis and first, second and third transmission lines electrically connected to the central section and extending therefrom. A first conductive member is electrically connected to the first transmission line with the first conductive member extending from the first transmission line to the second outward surface of the second dielectric member and being spaced from the second conductive layer and the first conductive member being mechanically and electrically connected to the first signal conductor of the circuit member by solder at the first interconnection location and having a first termination width no greater than the first width of the first signal conductor. A second conductive member is electrically connected to the second transmission line with the second conductive member extending from the second transmission line to the second outward surface of the second dielectric member and being spaced from the second conductive layer and the second conductive member being mechanically and electrically connected to the second signal conductor of the circuit member by solder at the second interconnection location and having a second termination width no greater than the second width of the second signal conductor. A third conductive member is electrically connected to the third transmission line.

In a further aspect, a method of designing a surface mount microwave device includes determining a desired impedance of a plurality of signal conductors on a circuit member, determining a conductor width of each signal conductors adjacent a termination location of each signal conductor, and determining a type of material and thickness of first and second dielectric layers. The method further includes determining desired shapes of first, second, and third transmission lines, determining a first termination width of a first conductive surface mount element that extends from the first transmission line to a mounting surface of the surface mount microwave device with the first termination width being no greater than the conductor width, and determining a second termination width of a second conductive surface mount element that extends from the second transmission line to the mounting surface with the second termination width being no greater than the conductor width.

### BRIEF DESCRIPTION OF THE DRAWINGS

FIG. 1 is a perspective view of a surface mount microwave device configured as an isolator;

FIG. 2 is a perspective view of the surface mount microwave device of FIG. 1 from a different perspective;

FIG. 3 is an exploded perspective view of the surface mount microwave device of FIG. 1;

FIG. 4 is a top plan view of conductive element and the lower layer of the surface mount microwave device of FIG. 1;

FIG. 5 is a perspective view of a second embodiment of a surface mount microwave device configured as a circulator;

FIG. 6 is a top plan view similar to FIG. 4 but of the conductive element and lower layer of the surface mount microwave device of FIG. 5;

FIG. 7 is a perspective view prior to mounting the surface mount microwave device on a circuit board;

FIG. 8 is an enlarged view of a portion of FIG. 7 but after the surface mount microwave device is mounted on the circuit board;

FIG. 9 is a perspective view of a third embodiment of a surface mount microwave device configured as an isolator depicting an alternate surface mounting member; and

FIG. 10 is a perspective view of a fourth embodiment of a surface mount microwave device configured as an isolator.

### DETAILED DESCRIPTION

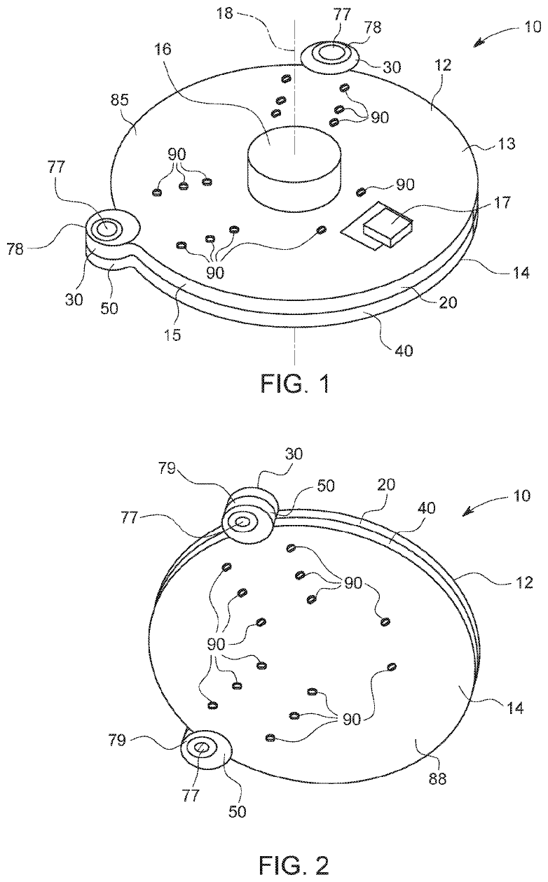

Referring to FIGS. 1-3, a surface mount microwave device 10 configured as a surface mount isolator includes a body 12 formed of a plurality of operatively connected layers, together with a magnetic element or component 16 and a load 17 mounted on the substrate. Body 12 has an upper or first surface 13, a lower or second surface 14 opposite the upper surface, and side edges or walls 15 that extend around the substrate. As depicted, the magnetic element 16 and the load 17 are mounted on the upper surface 13 with the magnetic element positioned along the central axis 18 of the body 12.

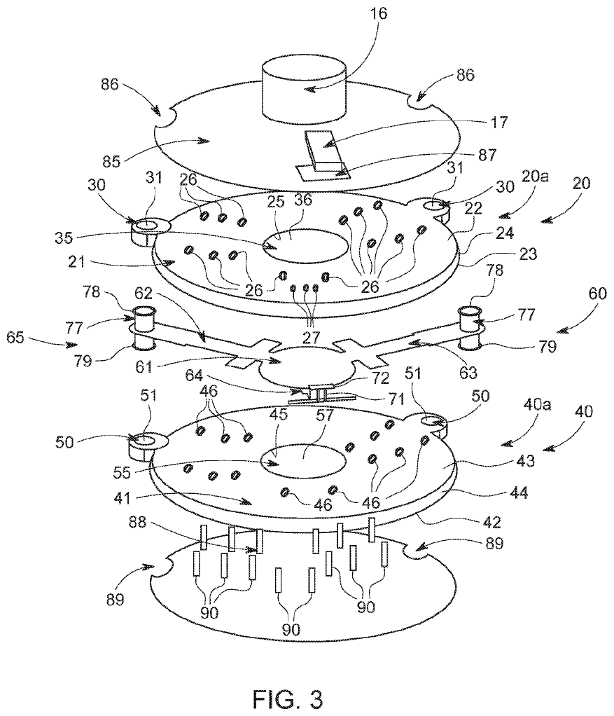

Referring to FIG. 3, a first or upper planar layer 20 includes a first dielectric or insulative member 21 configured as generally planar disc-shaped components. The first dielectric member 21 has an outward (or upper as depicted in the drawings) surface 22 and an oppositely facing inward (or lower as depicted in the drawings) surface 23, and a generally circular side edge 24 that interconnects the outward surface and the inward surface. The first dielectric member 21 further includes a central hole or bore 25 that extends between the outward surface 22 and the inward surface 23 and is located or positioned along central axis 18 of body 12.

If desired, first dielectric member 21 may also include a plurality of relatively small holes or bores 26 that extend between the outward surface 22 and the inward surface 23 and are spaced from the central bore 25. Dielectric member 21 may further include a plurality of relatively small holes or bores 27 that are utilized for interconnecting load 17 as described in further detail below.

Further, first dielectric member 21 may include a pair of spaced apart projections 30 that extend or project from the side edge 24. Each projection 30 includes a signal hole or bore 31 that extends between the outward surface 22 and the inward surface 23. Although each projection 30 is depicted as having an arcuate outer surface 32 or being somewhat semicircular, other shapes are contemplated.

First layer 20 further includes a first or upper ferrite element 35 configured as a generally planar disc shaped component that is sized to be secured within the central bore 25 of dielectric member 21 and along the central axis 18 of the body 12. The first ferrite element 35 includes an outward (or upper as depicted in the drawings) surface 36 and an oppositely facing inward (or lower as depicted in the drawings) surface (not shown), and a generally circular side edge (not shown) that interconnects the outward surface and the inward surface.

A second or lower planar layer 40 is generally similar to the first layer 20 and includes a second dielectric or insulative member 41 configured as generally planar disc-shaped components. The second dielectric member 41 has an outward (or lower as depicted in the drawings) surface 42 and an oppositely facing inward (or upper as depicted in the drawings) surface 43, and a generally circular side edge 44 that interconnects the outward surface and the inward surface. The outward surface 42 defines a mounting surface or direction of the surface mount microwave device 10 although, as described below, the outward surface includes second conductive layer 88 thereon. The second dielectric member 41 further includes a central hole or bore 45 that extends between the outward surface 42 and the inward surface 43 and is located or positioned along central axis 18 of body 12.

If desired, second dielectric member 41 may also include a plurality of relatively small holes or bores 46 that extend between the outward surface 42 and the inward surface 43 and are spaced from the central bore 45. The small bores 46 may be configured in a pattern that is identical to the pattern of the small bores 26 of first dielectric member 21.

Further, second dielectric member 41 may include a pair of spaced apart projections 50 that extend or project from the side edge 44. Each projection 50 includes a signal hole or bore 51 that extends between the outward surface 42 and the inward surface 43. Although each projection 50 is depicted as having an arcuate outer surface 52 or being somewhat semicircular, other shapes are contemplated.

Second layer 40 further includes a second or lower ferrite element 55 configured as a generally planar disc shaped component that is sized to be secured within the central bore 45 of dielectric member 41 and along the central axis 18 of the body 12. The second ferrite element 55 may be generally identical to first ferrite element 35 and includes an outward (or lower as depicted in the drawings) surface (not shown) and an oppositely facing inward (or upper as depicted in the drawings) surface 57, and a generally circular side edge (not shown) that interconnects the outward surface and the inward surface.

A first conductive layer 85 is disposed on the first layer 20 such as by applying the first conductive layer to the first outward surface 22 of first dielectric member 21 and the outward surface 36 of the first ferrite element 35. It should be noted that the first conductive layer 85 includes first cutouts or unplated areas 86 adjacent the bores 31 that extend through the projections 30 of the first dielectric member 21 and second cutouts 87 adjacent the load 17.

A second conductive layer 88 is disposed on the second layer 40 such as by applying the second conductive layer to the second outward surface 42 of second dielectric member 41 and the outward surface (not shown) of the second ferrite element 55. The second conductive layer 88 includes cutouts or unplated areas 89 adjacent the bores 51 that extend through the projections 50 of the second dielectric member 41.

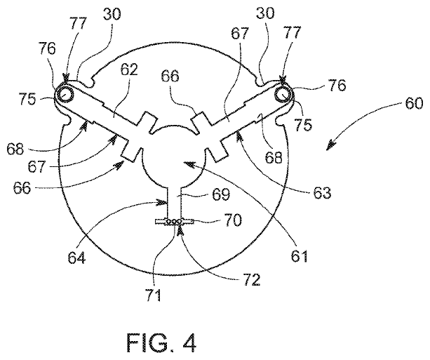

A conductive element 60 is disposed generally between the first layer 20 (i.e., the inward surface 23 of the first dielectric member 21 and the inward surface 37 of the first ferrite element 35) and the second layer 40 (i.e., the inward surface 43 of the second dielectric member 41 and the inward surface 57 of the second ferrite element 55). More specifically and referring to FIG. 4, the conductive third layer 60 has a circular central section 61 aligned with the central axis 18 of the body 12 and a first transmission line 62, a second transmission line 63, and a third transmission line 64 electrically connected to and extending radially from the central section 61. The central section 61, first transmission line 62, second transmission line 63, and third transmission lines 64 may be generally planar and form a third layer 65 between the first layer 20 and the second layer 40.

Each transmission line 62, 63, 64 may be configured to provide a desired electrical characteristics or impedance. In some applications, it may be desirable for each transmission line to have an impedance of 50 ohms. In the exemplary embodiment depicted in FIGS. 3-4, first transmission line 62 and second transmission lines 63 include, sequentially outward from the central section 61, a relatively wide first section 66 having a rectangular shape, a relatively narrow second section 67 having a rectangular shape, and a third section 68 having a rectangular shape and a width narrower than the first section and wider than the second section. The configuration of the conductive element 60 with the first and second conductive layers 85, 88 on opposite sides thereof define a stripline transmission line.

The first transmission line 62 and second transmission line 63 each includes a circular opening or bore 75 (FIG. 4) adjacent the outermost end 76 of the third section 68.

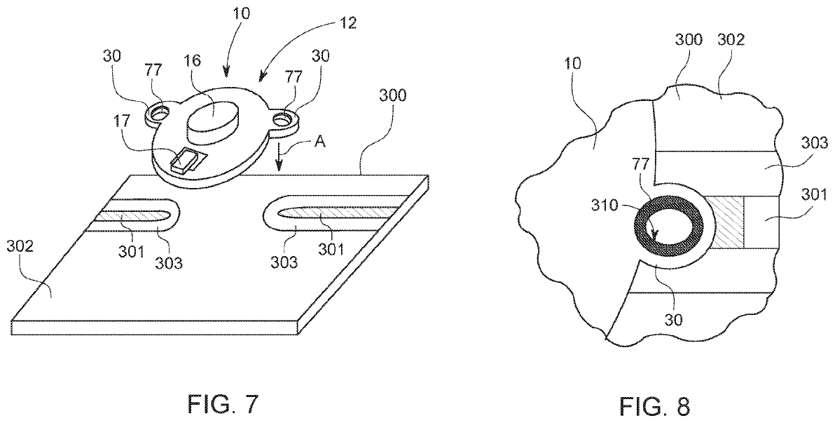

Each of the first transmission line 62 and the second transmission line 63 also includes a conductive surface mount element in the form of a hollow cylinder or barrel-shaped plated through hole or via 77 that is mechanically and electrically connected to the bore 75. As depicted in FIGS. 1-3, the via 77 extends vertically from the bore 75 through the signal bores 31 in the projections 30 of the first dielectric member 21 and through the signal bores 51 in the projections 50 of the second dielectric member 41. Solder (FIG. 8) interconnecting the internal surface or circumference of the vias 77 with the signal conductors or traces 301 (FIG. 7) on the circuit board or member 300 to which the surface mount microwave device 10 is mounted forms a mechanical and electrical connection between the conductive element 60 and the signal conductors.

In some embodiments, the vias 77 may include conductive material surrounding the upper and lower edges thereof. For example, a first circular section 78 may be located adjacent the outward surface 22 of the first dielectric member 21 and a second circular section 79 may be located adjacent the outward surface 42 of the second dielectric member 41. The first and second circular sections 78, 79 may be slightly larger than the diameter of the barrel of the via 77. In one example, the diameter of the first and second circular sections 78, 79 may be equal to the diameter of the signal bores 31, 51 plus twice the thickness of the plating of the wall of the via 77. Other shapes and other diameters are contemplated.

The first and second circular sections 78, 79 may exist based upon the manufacturing process and tolerances associated with the manufacture of the surface mount microwave device 10. For example, in one embodiment, the vias 77 and the first and second conductive layers 85, 88 may be formed at the same time or interconnected as a result of a plating operation. The cutouts 86, 89 of the first and second conductive layers 85, 88 may be formed by a subtractive or etching process. When performing the subtractive process, it may be desirable to avoid removing any material from the via 77. To reduce the likelihood of removing an material from the vias 77, a small amount of material may be left surrounding the vias that provide for manufacturing tolerances or act as a margin of error during the removal process.

As may be understood, the first and second circular sections 78, 79 are substantially smaller than traditional solder pads since they are not operating as the primary mechanical connection between the conductive element 60 and the circuit board upon which the surface mount microwave device 10 is mounted. (It should be noted that solder may migrate from the vias 77 to the first and second circular sections 78, 79 and thus the first and second circular sections may provide some mechanical connection between the surface mount microwave device 10 and the circuit board 300 but such connection will not be the primary mechanical connection. Accordingly, as used herein, a relatively small section of conductive material such as the first and second circular section 78, 79 that surrounds or extends from the barrel of the via 77 is not considered and is distinguished from traditional solder pads that are used for creating a mechanical and electrical connection by soldering a component to a circuit board or another device. In other words, the first and second circular sections 78, 79 are not solder pads and may be distinguished from solder pads since the primary electrical and mechanical connection between the vias 77 and a conductor or trace 301 (FIGS. 7-8) on circuit board 300 is from the solder 305 within the bore of the via 77 rather than the first and second circular sections.

In one example as described above, the diameter of the first and second circular sections 78, 79 may be equal to the diameter of the signal bores 31, 51 plus twice the thickness of the plating of the wall of the via 77. In another example, the first and second circular sections 78, 79 may be no larger than 0.2 mm wide. In still another example, the first and second circular sections 78, 79 may be no larger than 0.5 mm wide. In a further example, the area of the conductive material surrounding the upper or lower edge of a via 77 may be no greater than the cross-sectional area of the via. In each of these configurations, the conductive material surrounding the via 77 adjacent the mounting surface of the surface mount microwave device 10 shall not be considered a solder pad as its primary purpose is not to provide a solder connection between the surface mount microwave device and the circuit board 300.

Third transmission line 64 includes a first section 69 having a rectangular shape that extends radially outward from the central section 61 and a second section 70 having a rectangular shape that is wider than the first section. The third transmission line 64 also includes a plurality of relatively small vias 71 that interconnect the second section 70 to a solder pad 72 to which the load 17 may be electrically connected such as by soldering.

If the first dielectric member 21 includes the relatively small bores 26 and the second dielectric member 41 includes the relatively small bores 46, barrel-shaped plated through hole or vias 90 may extend through and be connected to the first conductive layer and the second conductive layer to electrically connect the two conductive layers at a plurality of locations. The vias 90 as well as the bores 26 and bores 46 are spaced from components of the conductive element 60 (e.g., central section 61, first transmission lines 62, second transmission line 63, and third transmission lines 64). In one embodiment, the distance between the vias 90 and the components of the conductive element 60 may be a distance equal to at least the thicknesses of the first dielectric member 21 and the second dielectric member 41.

Each of the first and second dielectric members 21, 41 may be formed of any desired material. In one example, the first and second dielectric members 21, 41 may be formed of materials used to form a circuit board such glass-reinforced fiberglass or any other resin or non-conductive material. The surface mount microwave device 10 includes only two dielectric layers 21, 41. This reduction in dielectric layers as compared to conventional surface mount microwave devices with greater than two dielectric layers provides improved electrical performance (through reduced insertion loss) and simplifies the manufacturing process. The ferrite elements 35, 55 are configured to be the same thickness as the dielectric member 21, 41 into which they are inserted. The magnetic element 16 may be a permanent magnetic or any other type of device for generating a desired magnetic field.

The conductive element 60, the first conductive layer 85, and the second conductive layer 88 may be formed of any desired material. In one example, the conductive element 60, the first conductive layer 85, and the second conductive layer 88 may be formed of copper. In addition, a protective coating (not shown) may be applied to the first conductive layer 85 and the second conductive layer 88, if desired. The magnetic element may be secured to the surface mount microwave device in any desired manner. In one example, the magnetic element may be secured with an adhesive.

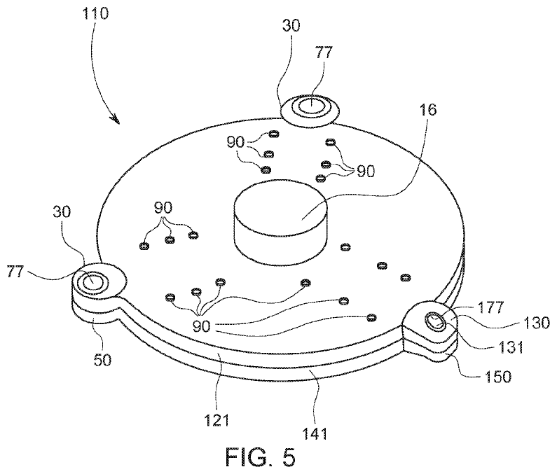

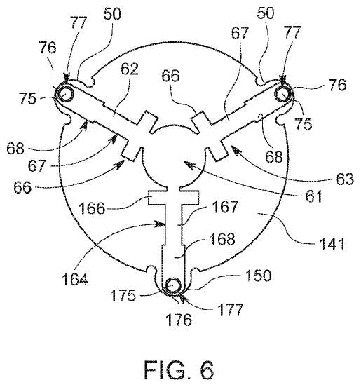

A plurality of alternate embodiments is contemplated. For example, although the surface mount microwave device 10 of FIGS. 1-4 is depicted as an isolator, the concepts disclosed herein are equally applicable to a surface mount circulator. Referring to FIG. 5, a surface mount microwave device 110 is depicted as a circulator that is identical to the surface mount isolator of FIGS. 1-4 except that the third transmission line 64 and the load 17 of the isolator are replaced with a third transmission line 164 (FIG. 6) that is identical to the first and second transmission lines 62, 63.

More specifically with like reference numbers referring to like elements, the first dielectric member 121 is provided with an additional projection 130 having a signal bore 131 and the second dielectric member 141 is provided with an additional projection 150 having a signal bore (not shown). A via 177 extends through the signal bores of the first and second dielectric members 121, 141. Referring to FIG. 6, the third transmission line 164 is identical to the first transmission line 62 and the second transmission line 63. Accordingly, as depicted, the third transmission line 164 includes, sequentially outward from the central section 61, a relatively wide first section 166 having a rectangular shape, a relatively narrow section 167 having a rectangular shape, and a third section 168 having a rectangular shape and width narrower than the first section and wider than the second section. The third transmission line 164 further includes a circular opening or bore 175 adjacent the outermost end 176 of the third section 168.

A via 177, similar to the vias 77 connected to the first transmission line 62 and the second transmission line 63, extends vertically from and is electrically connected to the bore 175 the third transmission line 164. The via 177 connected to the third transmission line 164 extends through the signal bore 131 of the additional projection 130 of the first dielectric member 21 and through the signal bore 151 of the additional projection 150 of the second dielectric member 41. As with the vias 77, via 177 is not mechanically or electrically connected to a solder pad on the surface mount microwave device 110.

Utilizing vias 77, 177 and eliminating solder pads on the surface mount microwave devices 10, 110 provides numerous advantages. First, the opening at the top of the vias 77, 177 may permit or simplify visual inspection of the solder joints 305 (FIG. 8) between the surface mount microwave device 10, 110 and the circuit board or member 300 (FIG. 7) upon which it is mounted. Second, the elimination of solder pads on surface mount microwave device 10, 110 improves electrical performance of the device (and thus the entire system) by maintaining a desired impedance and reducing insertion loss.

Still further, referring to FIGS. 7-8, the use of the vias 77, 177 to interconnect to a circuit board 300 permits the elimination of solder pads on the circuit board adjacent or at the interconnection between surface mount microwave device 10 and the circuit board. Circuit board 300 includes a pair of signal conductors or traces 301, a ground plane 302, and an unplated area 303 between each signal conductor and the ground plane. It should be noted that the signal conductors 301 have a constant width and are devoid of solder pads. In one example, the signal conductors 301 may have an impedance of 50 ohms. Surface mount microwave device 10 is mounted on the circuit board as depicted by arrow “A” and soldered thereto so that a solder joint or fillet 305 is formed between the inner surface or diameter of the vias 77 and the signal conductors 301. It should be noted that soldering the inner surface of the vias 77, 177 to the signal conductors 301 of circuit board 300 eliminates the need for an enlarged area (such as a solder pad) on circuit board 300 that is mechanically and electrically connected to the signal conductors 301. By eliminating the enlarged area (i.e., a solder pad) on the circuit board 300, improved electrical performance of the circuit board (and thus the entire system) may be achieved by maintaining a desired impedance and reducing insertion loss.

A further advantage is provided as operating speeds increase. When operating at relatively low speeds, the elimination of the solder pads may have less impact as compared to systems operating at relatively high speeds. For example, at higher frequencies, circuit traces on a circuit board or member are typically narrower as compared to those operating at lower frequencies. For example, at 3.5 GHz, 50 ohm circuit lines or traces may be as wide as 10 mm without adversely affecting performance but are often in the range of approximately 1.6-2.1 mm. At 15 GHz, 50 ohm circuit lines may only be as wide as approximately 2.0 mm without adversely affecting performance and at 28 GHz, 50 ohm circuit lines wider than approximately 0.5 mm may adversely affect performance. Accordingly, eliminating the increased width or size along a circuit trace as a result of solder pads may provide a significant advantage in system performance operating speeds increase.

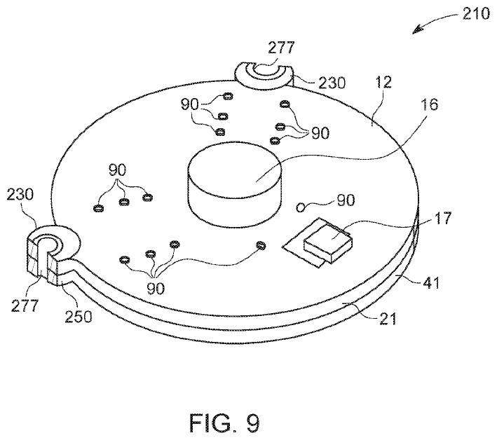

Referring to FIG. 9, another alternate embodiment of a surface mount microwave device 210 is depicted, in which like reference numbers refer to like elements. The surface mount microwave device 210 is similar to the surface mount microwave device 10 of FIGS. 1-4 but the projections 230, 250 and conductive surface mount elements are sectioned or cut so to form semi-circular vias 277 that have an approximately semi-circular shape. The semi-circular shape of vias 277 may provide an advantage in some applications by permitting improved or simplified visual inspection. For example, as the operating speeds of the system increase and the signal traces become narrower (e.g., 0.5 mm at 35 GHz), visual inspection through the hollow cylinder of vias 77, 177 may be more challenging. The open side of the semi-circular shape of vias 277 may permit greater visibility of the solder joint between the semi-circular via 277 and its associated circuit trace.

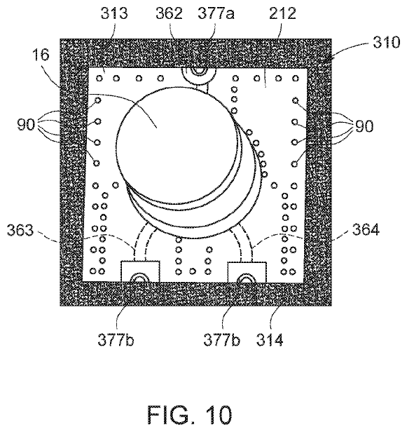

Still further alternate embodiments of a surface mount microwave device are contemplated. For example, rather than the body 12 being disk-shaped, the body may have other configurations such as being rectangular. In addition or in the alternative, rather than the vias 77, 177 being equally spaced or 120 degrees apart, the vias may be positioned at other desired locations. For example, referring to FIG. 10 in which like reference numbers refer to like elements, a surface mount microwave device 310 is depicted with a rectangular body 312. A first transmission line 362 is mechanically and electrically connected to one semi-circular via 377a disposed along a first edge 313 of the body. The second and third transmission lines 363, 364 are mechanically and electrically connected to respective ones of a pair of semi-circular vias 377b along a second, opposite edge 314 of the body.

It should be noted that the surface mount microwave devices 10, 110, 210, 310 described herein include only two dielectric members that form portions of the first and second layers of the devices. In some embodiments, the surface mount microwave devices 10, 110, 210, 310 may include more than two dielectric members but also utilize the cylindrical or semi-circular conductive surface mount elements described herein. Still further, in some embodiments, the surface mount microwave devices 10, 110, 210, 310 described herein may include only two dielectric members but include other embodiments of a conductive surface mount element. In still other embodiments, only one layer 20, 40 may include a ferrite element 35, 55 to form an asymmetrical stripline transmission line. In such case, the layer without the ferrite element may have a solid dielectric member.

In one embodiment, to design the surface mount microwave device 10, the desired impedance of the device may be specified. Based upon the desired impedance, the type of material and thickness of the first and second dielectric layers 21, 41 as well as the shape of the first, second, and third transmission lines 62, 63, 64 may be determined. To determine the diameter or width of the conductive surface mount elements (e.g., vias 77, 177 or semi-circular vias 277), the width of the signal conductors 301 on the circuit board 300 may be specified or determined based upon the type of material from which the circuit board is formed and the desired impedance of the circuit trace. The diameter of the vias 77, 177 or semi-circular vias 277 may be set or specified so that the inner diameter of the vias or semi-circular vias is equal to or smaller than the width of the signal conductors. The surface mount microwave device 10 may then be manufactured with the desired configuration and with the vias 77, 177 or semi-circular vias 277 having the desired dimensions.

In the example described above in which a 50 ohm circuit line for operating at 15 GHz is approximately 2.0 mm wide, the inner diameter of the vias 77, 177 or semi-circular vias 277 may be configured to be 2.0 mm or less. Similarly, in the example described above in which a 50 ohm circuit line for operating at 28 GHz is approximately 0.5 mm wide, the inner diameter of the vias 77, 177 or semi-circular vias 277 may be configured to be 0.5 mm or less.

In any example and particularly in connection with extremely small vias such as those 1.0 and smaller, it may be desirable to utilize the semi-circular vias 277 to improve the ability to visually inspect the solder joints. As with the circular vias 77, 177, the inner diameter of the semi-circular vias 277 may still be configured to be no larger than the width of the circuit line 301 on the circuit board 300.

It will be appreciated that the foregoing description provides examples of the disclosed system and technique. However, it is contemplated that other implementations of the disclosure may differ in detail from the foregoing examples. All references to the disclosure or examples thereof are intended to reference the particular example being discussed at that point and are not intended to imply any limitation as to the scope of the disclosure more generally. All language of distinction and disparagement with respect to certain features is intended to indicate a lack of preference for those features, but not to exclude such from the scope of the disclosure entirely unless otherwise indicated.

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context.

Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context. Still further, the advantages described herein may not be applicable to all embodiments encompassed by the claims.

1. A microwave device comprising:
a first dielectric member, the first dielectric member having a first outward surface and an oppositely facing first inward surface;
a first conductive layer disposed on the first outward surface of the first dielectric member;
a second dielectric member, the second dielectric member having a second outward surface defining a mounting direction of the microwave device and an oppositely facing second inward surface;
a second conductive layer disposed on the second outward surface of the second dielectric member;
one of the first dielectric member and the second dielectric member having a central bore aligned with a central axis of the microwave device and a ferrite element disposed within the central bore;
a magnetic element aligned with the central bore;
a conductive element disposed between the first inward surface of the first dielectric member and the second inward surface of the second dielectric member, the conductive element having a central section along with the central axis and first, second and third transmission lines electrically connected to the central section and extending therefrom,
a first conductive member electrically connected to the first transmission line, the first conductive member extending from the first transmission line to the second outward surface of the second dielectric member and being spaced from the second conductive layer;
a second conductive member electrically connected to the second transmission line, the second conductive member extending from the second transmission line to the second outward surface of the second dielectric member and being spaced from the second conductive layer;
a third conductive member electrically connected to the third transmission line; and
the first conductive member and the second conductive member are not electrically connected to solder pads on the microwave device.

2. The device of claim 1, wherein the first conductive member and the second conductive member are hollow cylinders.

3. The device of claim 2, wherein the first conductive member is disposed adjacent an edge of the second dielectric member at a first location and the second conductive member is disposed adjacent the edge of the second dielectric member at a second location spaced from the first location.

4. The device of claim 3, wherein the second dielectric member includes a first arcuate projection extending from the edge of the second dielectric member at the first location and a second arcuate projection extending from the edge of the second dielectric member at the second location, the first conductive member extending through at least a portion of the first arcuate projection and the second conductive member extending through at least a portion of the second arcuate projection.

5. The device of claim 1, wherein the first conductive member and the second conductive member are hollow semi-cylinders.

6. The device of claim 5, wherein the first conductive member intersects with an edge of the second dielectric member at a first location and the second conductive member intersects with the edge of the second dielectric member at a second location spaced from the first location.

7. The device of claim 1, wherein the third conductive member extends from the third transmission line to the second outward surface of the second dielectric member and being spaced from the second conductive layer, the third conductive member being devoid of a solder pad.

8. The device of claim 7, wherein the third conductive member is a hollow cylinder.

9. The device of claim 8, wherein the second dielectric member further includes a third arcuate projection extending from the edge of the second dielectric member at a third location spaced from the first location and the second location and the third conductive member extending through at least a portion of the third arcuate projection.

10. The device of claim 7, wherein the third conductive member is a hollow semi-cylinder.

11. The device of claim 10, wherein the third conductive member intersects with the edge of the second dielectric member at a third location.

12. The device of claim 1, wherein the conductive element comprises a planar layer including the central section and the first, second and third transmission lines.

13. The device of claim 1, further including a load electrically connected to the third conductive member.

14. The device of claim 1, wherein the microwave device includes only two dielectric members.

15. An assembly comprising:
a circuit member comprising:
a mounting surface;
a ground plane; and
first and second signal conductors spaced from the ground plane, and
a microwave device comprising:
a first dielectric member, the first dielectric member having a first outward surface and an oppositely facing first inward surface;
a first conductive layer disposed on the first outward surface of the first dielectric member;
a second dielectric member, the second dielectric member having a second outward surface defining a mounting direction of the microwave device and an oppositely facing second inward surface;
a second conductive layer disposed on the second outward surface of the second dielectric member;
one of the first dielectric member and the second dielectric member having a central bore aligned with a central axis of the microwave device and a ferrite element disposed within the central bore;
a magnetic element aligned with the central bore;
a conductive element disposed between the first inward surface of the first dielectric member and the second inward surface of the second dielectric member, the conductive element having a central section along with the central axis and first, second and third transmission lines electrically connected to the central section and extending therefrom,
a first conductive member electrically connected to the first transmission line, the first conductive member extending from the first transmission line to the second outward surface of the second dielectric member and being spaced from the second conductive layer, the first conductive member being mechanically and electrically connected to the first signal conductor of the circuit member by solder at a first interconnection;
a second conductive member electrically connected to the second transmission line, the second conductive member extending from the second transmission line to the second outward surface of the second dielectric member and being spaced from the second conductive layer, the second conductive member being mechanically and electrically connected to the second signal conductor of the circuit member by solder at a second interconnection;
a third conductive member electrically connected to the third transmission line; and
the first and second signal conductors are devoid of solder pads adjacent the first and second interconnections.

16. The assembly of claim 15, wherein interconnections the first conductive member and the second conductive member being devoid of solder pads adjacent the first and second interconnections.

17. The assembly of claim 15, wherein the first conductive member and the second conductive member are hollow cylinders and solder extends between an inner surface of the first conductive member and the first signal conductor and an inner surface of the second conductive member and the second signal conductor.

18. The assembly of claim 15, wherein the first conductive member and the second conductive member are hollow semi-cylinders and solder extends between an inner surface of the first conductive member and the first signal conductor and an inner surface of the second conductive member and the second signal conductor.

19. The assembly of claim 15, wherein circuit member further comprises a third signal conductor spaced from the ground plane, and the third conductive member of the microwave device extends from the third transmission line to the second outward surface of the second dielectric member and is spaced from the second conductive layer, the third conductive member being mechanically and electrically connected to the third signal conductor of the circuit member by solder at a first interconnection, the third signal conductor being devoid of a solder pad adjacent the third conductive member.

20. The assembly of claim 19, wherein the third conductive member is devoid of a solder pad adjacent the third signal conductor.

21. An assembly comprising:
a circuit member comprising:
a mounting surface;
a ground plane;
a first signal conductor spaced from the ground plane, the first signal conductor being devoid of a solder pad and having a first width adjacent a first interconnection location; and
a second signal conductor spaced from the ground plane, the second signal conductor being devoid of a solder pad and having a second width adjacent a second interconnection location; and
a microwave device comprising:
a first dielectric member, the first dielectric member having a first outward surface and an oppositely facing first inward surface;
a first conductive layer disposed on the first outward surface of the first dielectric member;
a second dielectric member, the second dielectric member having a second outward surface defining a mounting direction of the microwave device and an oppositely facing second inward surface;
a second conductive layer disposed on the second outward surface of the second dielectric member;
one of the first dielectric member and the second dielectric member having a central bore aligned with a central axis of the microwave device and a ferrite element disposed within the central bore;
a magnetic element aligned with the central bore;
a conductive element disposed between the first inward surface of the first dielectric member and the second inward surface of the second dielectric member, the conductive element having a central section along with the central axis and first, second and third transmission lines electrically connected to the central section and extending therefrom,
a first conductive member electrically connected to the first transmission line, the first conductive member extending from the first transmission line to the second outward surface of the second dielectric member and being spaced from the second conductive layer, the first conductive member being mechanically and electrically connected to the first signal conductor of the circuit member by solder at the first interconnection location and having a first termination width no greater than the first width of the first signal conductor;
a second conductive member electrically connected to the second transmission line, the second conductive member extending from the second transmission line to the second outward surface of the second dielectric member and being spaced from the second conductive layer, the second conductive member being mechanically and electrically connected to the second signal conductor of the circuit member by solder at the second interconnection location and having a second termination width no greater than the second width of the second signal conductor; and
a third conductive member electrically connected to the third transmission line.

22. The assembly of claim 21, wherein the first conductive member and the second conductive member are hollow cylinders and solder extends between an inner surface of the first conductive member and the first signal conductor and an inner surface of the second conductive member and the second signal conductor, the first and second termination widths being equal to the diameter of the hollow cylinders.

23. The assembly of claim 21, wherein the first conductive member and the second conductive member are hollow semi-cylinders and solder extends between an inner surface of the first conductive member and the first signal conductor and an inner surface of the second conductive member and the second signal conductor, the first and second termination widths being equal to the diameter of the hollow semi-cylinders.

24. (canceled)
